(19) United States
(12) Patent Application Publication
(10) Pub. No.: US 2025/0254940 A1
(43) Pub. Date: Aug. 7, 2025

(54) SEMICONDUCTOR STRUCTURE WITH BLOCKING FEATURES FORMED WITHIN BASE EPITAXY LAYERS AND METHOD FOR MANUFACTURING THE SAME

(71) Applicant: TAIWAN SEMICONDUCTOR MANUFACTURING COMPANY, LTD., Hsinchu (TW)

(72) Inventors: Tsungyu HUNG, Hsinchu (TW); Chia-Ling PAI, Hsinchu (TW); I-Ming CHANG, Hsinchu (TW)

(73) Assignee: TAIWAN SEMICONDUCTOR MANUFACTURING COMPANY, LTD., Hsinchu (TW)

(21) Appl. No.: 18/435,685

(22) Filed: Feb. 7, 2024

(51) Int. Cl. H01L 29/06; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 64/017

(57) ABSTRACT

A method for manufacturing a semiconductor structure includes: forming stacks on a substrate; forming gate structures on the stacks, portions of the stacks are exposed from the gate structures; forming trenches respectively in the portions of the stacks and respectively extending into upper portions of the substrate, after forming the trenches, each of the stacks being formed into stack portions each including first nanosheets, and second nanosheets that alternate with the first nanosheets; forming base epitaxy layers respectively at bottoms of the trenches; performing an ion implantation process to obtain doped base epitaxy layers, each of which is embedded with a blocking feature; and forming source/drain portions respectively in the trenches on the doped base epitaxy layers such that each of the source/drain portions is isolated from the substrate through the blocking feature in a respective one of the doped base epitaxy layers.

### BACKGROUND

For transistors, source/drain portions play an important role in inducing channel strain. Since source/drain portions with good quality may enhance performance of the transistors, improvements are urged in the process of forming source/drain portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 15 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a semiconductor structure including base blocking features formed within base epitaxy layers, and method for manufacturing the same. Source/drain portions in the semiconductor structure are formed by epitaxy growth of a silicon-based semiconductor material directly on upper surfaces of the base epitaxy layers, respectively. In the case that such upper surfaces include silicon with single crystal structure, the source/drain portions formed thereon are more likely to have superior quality, for instance, with small amount of voids, with single crystal structure, etc. In order to retain the base epitaxy layers having the upper surfaces including silicon with single crystal structure for subsequent epitaxy growth of the source/drain portions, the blocking features, that are configured to avoid current leakages from the source/drain portions through the base epitaxy layers, are formed inside the base epitaxy layers beneath the upper surfaces including silicon with single crystal structure. Such blocking features may be formed by performing an ion implantation process to dope dopants into interior of the base epitaxy layers at a relatively high temperature, e.g., not less than 500° C., so as to retain the upper surfaces including silicon with single crystal structure.

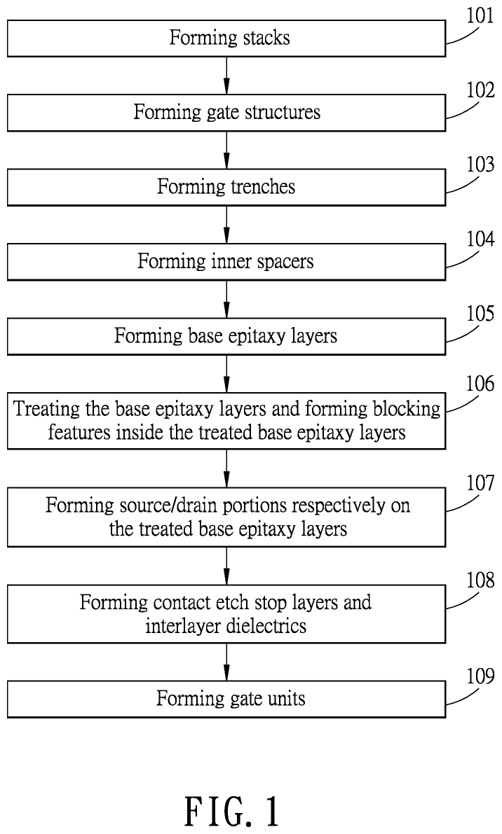

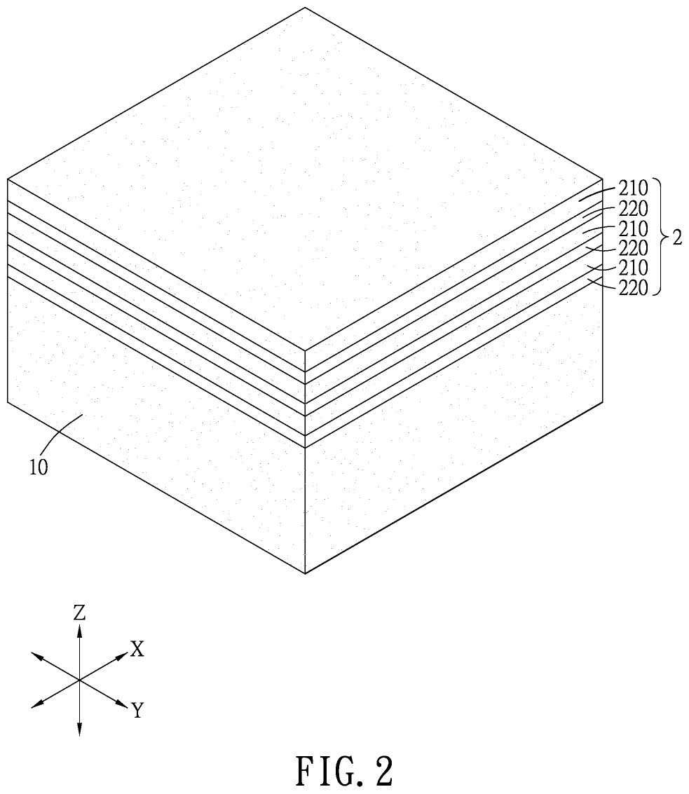

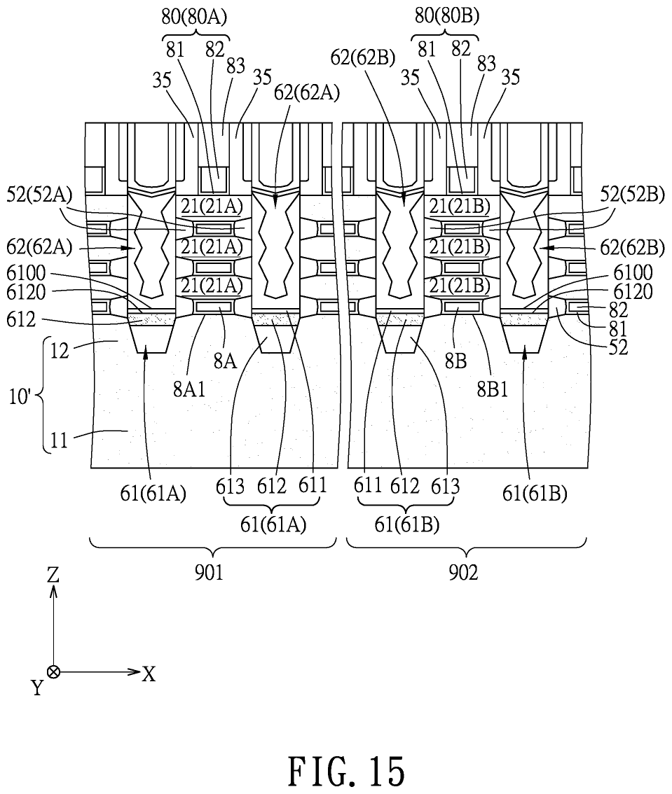

FIG. 1 is a flow diagram illustrating a method for manufacturing the semiconductor structure (e.g., the semiconductor structure as shown in FIG. 15) in accordance with some embodiments. FIGS. 2 to 15 illustrate schematic views of intermediate stages of the method in accordance with some embodiments. Some repeating structures are omitted in FIGS. 2 to 15 for the sake of brevity. Additional steps can be provided before, after or during the method, and some of the steps described herein may be replaced by other steps or be eliminated. In some embodiments, the semiconductor structure may include nanosheet transistors (or the likes, but are not limited thereto) that are formed with the source/drain portions and base epitaxy layers as aforementioned.

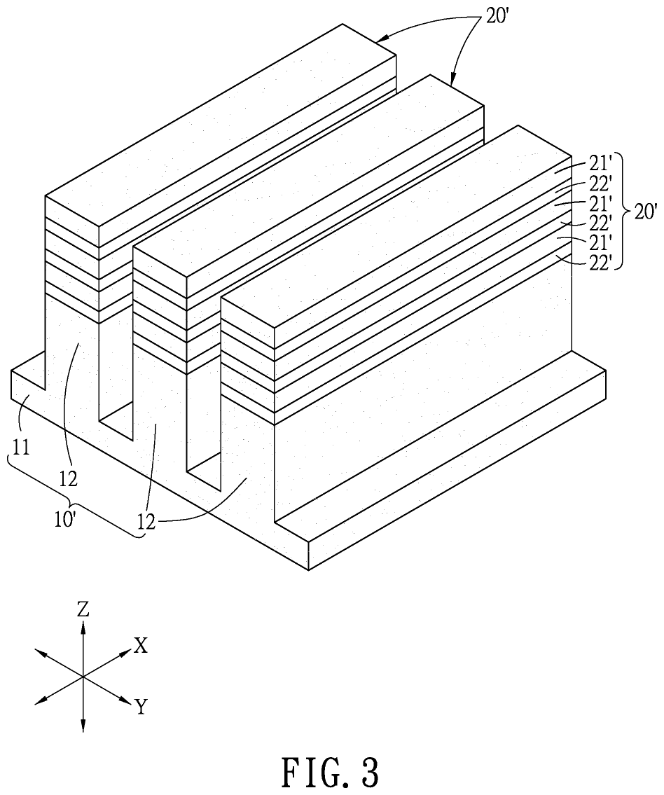

Referring to FIG. 1 and the example illustrated in FIG. 3, the method begins at step 101, where stacks 20′ are respectively formed on fin portions 12 of a patterned substrate 10′. In some embodiments, the step 101 includes two sub-steps that are respectively illustrated in FIGS. 2 and 3.

Referring to FIG. 2, in a first sub-step of step 101, a starting material stack 2 is formed on a substrate 10.

The substrate 10 may be made of elemental semiconductor materials, such as silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate 10 may be doped with p-type impurities or n-type impurities, or undoped. In addition, the substrate 10 may be a bulk silicon substrate, a silicon-on-insulator (SOI) substrate, or a germanium-on-insulator (GOI) substrate. Other suitable materials for forming the substrate 10 are within the contemplated scope of disclosure.

The starting material stack 2 includes at least one first nanosheet material layer 210 and at least one second nanosheet material layer 220. Numbers of each of the first nanosheet material layer 210 and the second nanosheet material layer 220 may be determined according to practical needs and product design. As shown in FIG. 2, there are three of the first nanosheet material layers 210, and three of the second nanosheet material layers 220. The first and second nanosheet material layers 210, 220 alternate with each other along a Z direction. In some embodiments, the first nanosheet material layers 210 may include silicon, and the second nanosheet material layer 220 may include silicon germanium. In certain embodiments, the first nanosheet material layers 210 may be made of a material same as that of the substrate 10. In some embodiments, a bottommost one of the second nanosheet material layers 220 is disposed beneath a bottommost one of the first nanosheet material layers 210. Other suitable numbers and/or materials of each of the first and second nanosheet material layers 210, 220 are within the contemplated scope of the present disclosure.

Referring to FIG. 3, in a second sub-step of step 101, the substrate 10 (see FIG. 2) is patterned into the patterned substrate 10′, and the starting material stack 2 is patterned into a plurality of the stacks 20′. The patterned substrate 10′ includes a base portion 11 and a plurality of the fin portions 12 that are disposed on the base 11. The fin portions 12 are spaced apart from each other along a Y direction transverse (e.g., perpendicular to) with the Z direction, and are each elongated in an X direction transverse (e.g., perpendicular to) with the Z direction and the Y direction. The stacks 20′ are respectively disposed on the fin portions 12. Each of the stacks 20′ includes first nanosheet layers 21′ (formed from the first nanosheet material layers 210) and second nanosheet layers 22′ (formed from the second nanosheet material layers 220) that alternate with each other.

In some embodiments, a patterned mask (not shown) is first formed on the starting material stack 2 (see FIG. 2), followed by patterning the starting material stack 2 and the substrate 10 through the patterned mask. The patterned mask may be removed after the patterning process. Other suitable processes for forming the stacks 20′ and the patterned substrate 10′ are within the contemplated scope of the present disclosure.

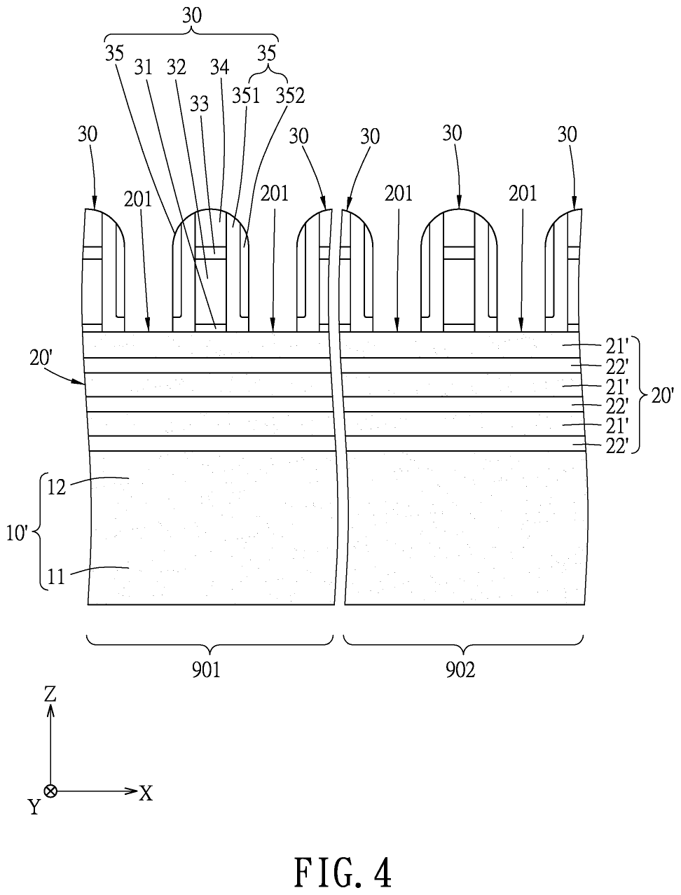

Referring to FIG. 1 and the example illustrated in FIG. 4, the method proceeds to step 102, where gate structures 30 are formed on the stacks 20′. FIG. 4 is a cross-sectional view of one of the stacks 20′ taken along the X direction after completing step 102 in accordance with some embodiments. The patterned substrate 10′ has a first region 901 and a second region 902 for forming two different types of devices. Each of the stacks 20′ may be disposed on one of the first and second regions 901, 902 or disposed on both the first and second regions 901, 902. One of the stacks 20′ shown in FIG. 4 is disposed on both the first and second regions 901, 902. In some embodiments, the first region 901 is used for forming an n-type transistor and may be undoped or doped with p-type impurities, while the second region 902 is used for forming a p-type transistor and may be undoped or doped with n-type impurities.

The gate structures 30 may each elongate along the Y direction over one or more of the stack(s) 20′ (one of the stacks 20′ is shown in FIG. 4). In addition, the gate structures 30 are spaced apart from each other in the X direction, such that portions 201 of the stacks 20′ are exposed from the gate structures 30.

In some embodiments, as shown in FIG. 4, each of the gate structures 30 includes a dummy dielectric 31, a dummy gate 32, a polish stop layer 33, a hard mask 34 and a pair of gate spacers 35. The dummy dielectric 31, the dummy gate 32, the polish stop layer 33, and the hard mask 34 are sequentially formed as a stack on upper surfaces of the stacks 20′, and are sandwiched by the pair of the gate spacers 35. In some embodiments, the dummy dielectric 31 may include a dielectric material such as silicon oxide, silicon nitride, but is not limited thereto. The dummy gate 32 may include polycrystalline silicon, or the like, but is not limited thereto. The polish stop layer 33, the hard mask 34 and the gate spacers 35 may each include a dielectric material such as silicon oxide, silicon nitride, but is not limited thereto, though the polish stop layer 33 and the hard mask 34 are made of different materials. Each of the gate spacers 35 may have a single-layer structure, or a multi-layered structure. For instance, as shown in FIG. 4, each of the gate spacers 35 may have an inner spacer layer 351, and an outer spacer layer 352 that are made of different dielectric materials.

In some embodiments, step 102 may include sub-steps of: sequentially forming a dielectric material film (not shown, for forming the dummy dielectric 31), a gate material layer (not shown, for forming the dummy gate 32), a polish stop material layer (not shown, for forming the polish stop layer 33) and the hard mask 34 on the stacks 20′; patterning the dielectric material film, the gate material layer and the polish stop material layer through the hard mask 34 so as to obtain the dummy dielectric 31, the dummy gate 32 and the polish stop layer 33 of each of the gate structures 30; conformally forming a first spacer material layer (not shown, for forming the inner spacer layer 351) and a second spacer material layer (not shown, for forming the outer spacer layer 352) over the dummy dielectric 31, the dummy gate 32, the polish stop layer 33, and the hard mask 34 of each of the gate structures 30, and the stacks 20′; and removing any excess amount of the first and second spacer material layers, so as to obtain the pair of the gate spacers 35 of each of the gate structures 30. The gate structures 30 are thereby obtained. Other suitable materials and/or processes for forming the gate structures 30 are within the contemplated scope of the present disclosure.

In some embodiments, prior to forming the gate structures 30, isolation features (not shown) are formed between any two adjacent ones of the fin portions 12. The isolation features may be formed by depositing an isolation material over the structure shown in FIG. 3, followed by a planarization process and an etch-back process to remove any excess amount of the isolation material. The isolation features are thus obtained, and the stacks 20′ are exposed from the isolation features. In step 102, the gate structures 30 are formed over the stacks 20′, and also the isolation features.

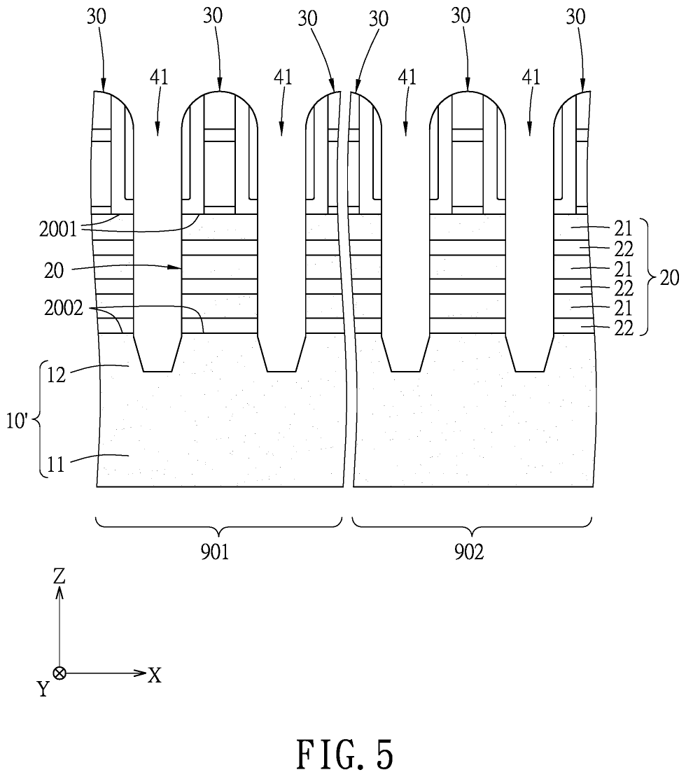

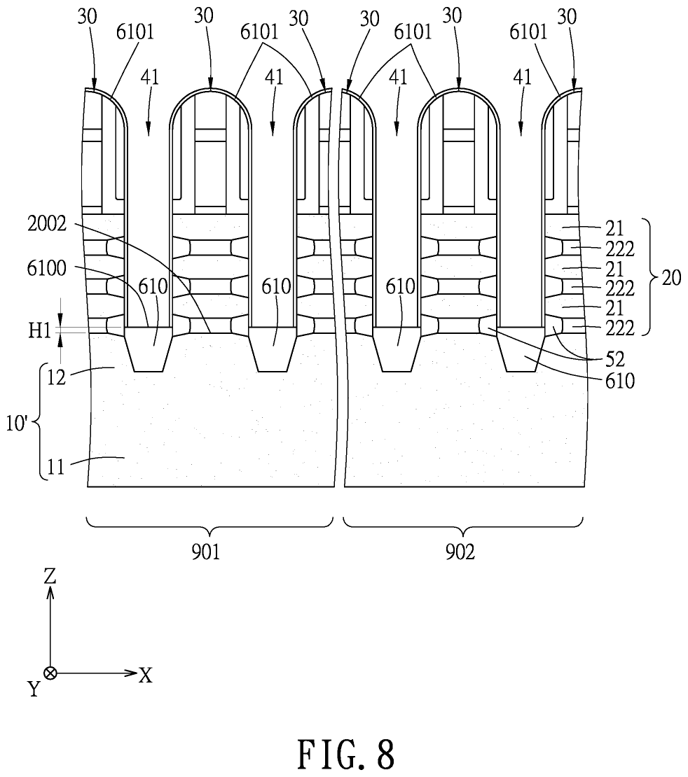

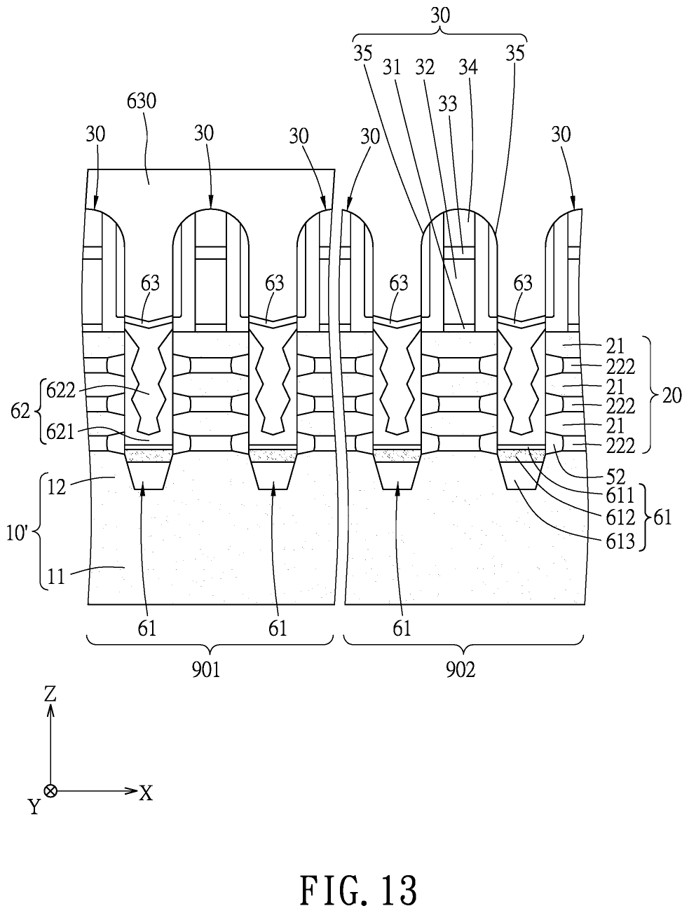

Referring to FIG. 1 and the example illustrated in FIG. 5, the method proceeds to step 103, where trenches 41 are formed. FIG. 5 illustrates a structure after completing step 103, which is subsequent to the structure shown in FIG. 4. The trenches 41 serve as source/drain recesses to accommodate base epitaxy layers 610 (see FIG. 8) and source/drain portions 62 (see FIG. 13) formed in subsequent steps.

The trenches 41 are respectively formed in the exposed portions 201 of the stacks 20′ (see FIG. 4) and respectively extend into upper portions of the patterned substrate 10′ (e.g., upper portions of the fin portions 12). Any suitable patterning processes for forming the trenches 41, such as dry or wet etching, but is not limited thereto, may be used to form the trenches 41. After step 103, as shown in FIG. 5, each of the stacks 20′ shown in FIG. 4 is formed into stack portions 20 each having an upper surface 2001 (on which a corresponding one of the gate structures 30 is formed) and a bottom surface 2002 that are opposite to each other in the Z direction. Each of the stack portions 20 includes first nanosheets 21 (obtained from patterning the first nanosheet layers 21′), and second nanosheets 22 (obtained from pattering the second nanosheet layers 22′). The fin portions 12 are patterned to border bottoms of the trenches 41.

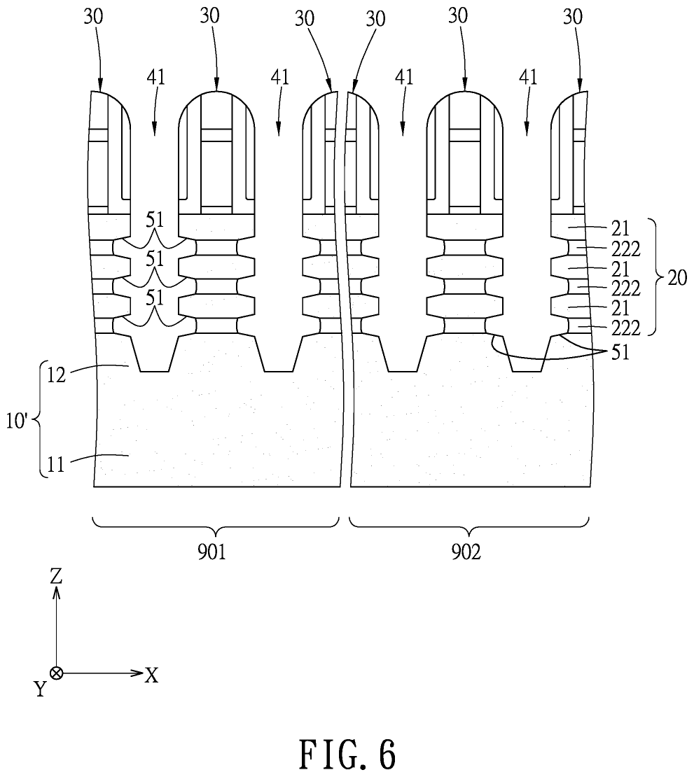

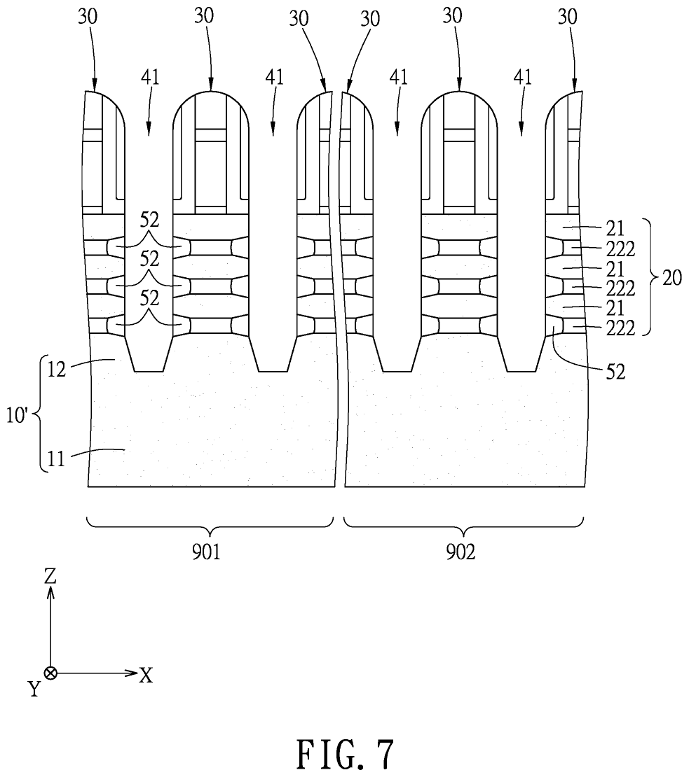

Referring to FIG. 1 and the examples illustrated in FIG. 7, the method proceeds to step 104, where the second nanosheets 22 are recessed, and inner spacers 52 are formed. Step 104 may include two sub-steps that are respectively illustrated in FIGS. 6 and 7. The structures shown in FIGS. 6 and 7 are subsequent to that shown in FIG. 5.

Referring to FIG. 6, in some embodiments, a first sub-step of step 104 includes recessing the second nanosheets 22 of each two adjacent ones of the stack portions 20 through a respective one of the trenches 41 so as to form multiple pairs of lateral recesses 51. Hereinafter, the recessed second nanosheets are denoted by numeral 222. Any suitable recessing processes, such as dry or wet etching, but is not limited thereto, may be used to form the lateral recesses 51.

Referring to FIG. 7, a second sub-step of step 104 includes forming multiple pairs of the inner spacers 52 in the multiple pairs of the lateral recesses 51, respectively. The inner spacers 52 may be formed using any suitable processes known in the art, such as deposition, followed by etching, but are not limited thereto. In some embodiments, the inner spacers may include a dielectric material such as silicon oxide, silicon nitride, silicon oxynitride, silicon carbide, or the likes, or combinations thereof. Other suitable materials and/or methods for forming the inner spacers 52 are within the contemplated scope of the present disclosure. By completing step 104, the multiple pairs of the inner spacers 52 are accessible through the respective one of the trenches 41.

Referring to FIG. 1 and the example illustrated in FIG. 8, the method proceeds to step 105, where base epitaxy layers 610 are respectively formed at bottoms of the trenches 41.

The base epitaxy layers 610 may include a semiconductor material, such as a silicon-based semiconductor material (e.g., silicon, silicon germanium, or the like), or other semiconductor material, but is not limited thereto. The base epitaxy layers 610 may be formed by an epitaxy growth process such as chemical vapour deposition (CVD), or molecular beam epitaxy (MBE), but is not limited thereto. Other suitable materials and/or methods for forming the base epitaxy layers 610 are within the contemplated scope of the present disclosure. In some embodiments, the base epitaxy layers 610 include silicon that are grown with single crystal structure, which favors the source/drain portions 62 (see FIG. 13) grown thereon to also have single crystal structure.

An upper surface 6100 of each of the base epitaxy layers 610 is at a level higher than a level of the bottom surface 2002 of each of two corresponding adjacent ones of the stack portions 20 by a first height H1. In some embodiments, the first height H1 may range from about 2 nm to about 10 nm, such as about 5 nm to 10 nm, but is not limited thereto. Please note that in this step, for each of the stack portions 20, the bottom surface 2002 is constituted by a lower surface of a bottommost one of the recessed second nanosheets 222.

In some embodiments, as shown in FIG. 8, step 105 may further include forming spacers 6101 to cover the stack portions 20, the inner spacers 52, and the gate structures 30.

The spacers 6101 are formed by first conformally depositing a spacer material layer (not shown) over the stack portions 20, the inner spacers 52, the gate structures 30, and the base epitaxy layers 610, followed by an etching process to remove portions of the spacer material layer respectively covering the base epitaxy layers 610. The spacers 6101 may include silicon oxide, or silicon nitride, or the likes. The spacers 6101 may have a thickness ranging from about 1 nm to about 4 nm, so as to provide sufficient protection to the stack portions 20 during the subsequent step 106.

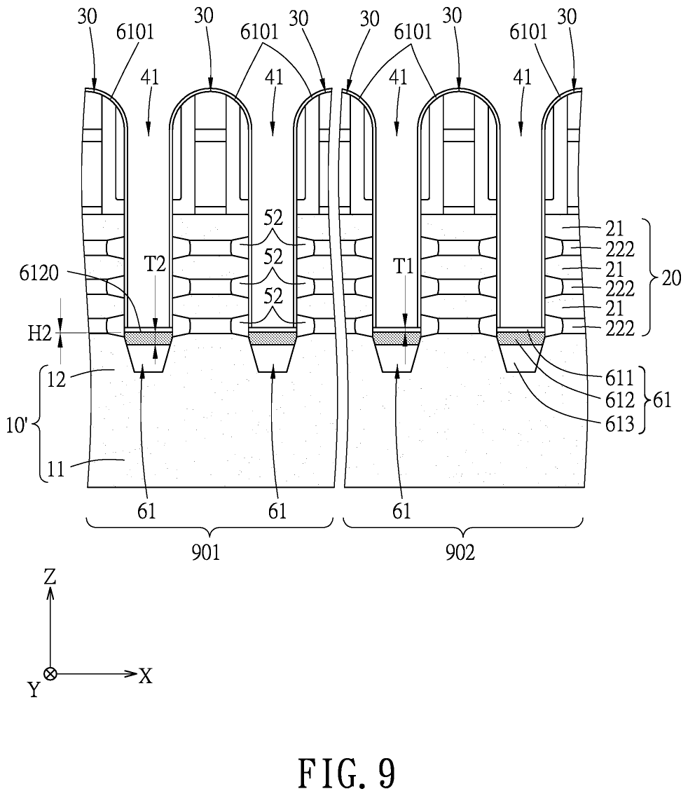

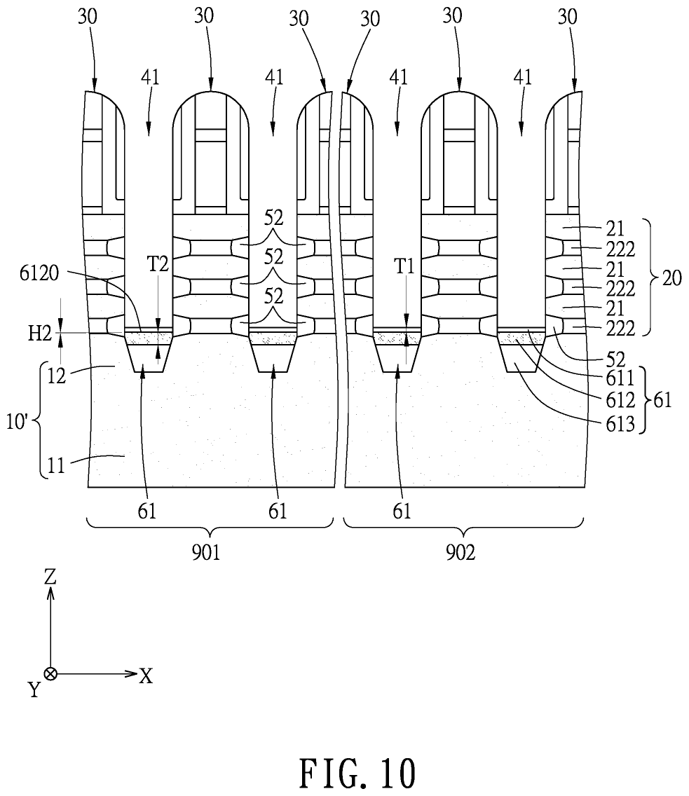

Referring to FIG. 1 and the examples illustrated in FIGS. 9 and 10, the method proceeds to step 106, where the base epitaxy layers 610 (see FIG. 8) are treated. Specifically, a middle portion of each of the base epitaxy layers 610 is formed into a blocking feature 612. Step 106 may include two sub-steps that are respectively illustrated in FIGS. 9 and 10, and the treated base epitaxy layers are denoted by the numeral 61.

Referring to FIG. 10, by completing step 106, each of the treated base epitaxy layers 61 includes an undoped upper portion 611, an undoped lower portion 613, and a doped middle portion interposed between the undoped upper and lower portions 611, 613. The doped middle portion serves as the blocking feature 612. In some embodiments, the undoped upper portion 611 may have a thickness (T1) ranging from about 3 nm to about 5 nm, and the blocking feature 612 may have a thickness (T2) ranging from about 5 nm to about 20 nm, but is not limited thereto.

In each of the treated base epitaxy layers 61, the blocking feature 612 is covered by the undoped upper portion 611, such that the blocking feature 612 is prevented from being exposed from a respective one of the trenches 41. For instance, in some embodiments, the blocking feature 612 is fully covered by the undoped upper portion 611. As such, for each of the treated base epitaxy layers 61, upper surface of the undoped upper portion 611 makes up an upper surface of the treated base epitaxy layer 61. Please note that the undoped upper portions 611 of the treated base epitaxy layers 61 respectively serve as the growing surfaces of the source/drain portions 62 (see FIG. 13) in subsequent step. The single crystal silicon in the undoped upper portions 611, and especially at the upper surfaces thereof, are retained after step 106 so as to allow the source/drain portions 62 to be grown with single crystal structure.

The blocking features 612 of the treated base epitaxy layers 61 are configured to prevent current leakage from the source/drain portions 62 (sequentially formed, see FIG. 13) into the fin portions 12, and thus are formed with desirable current blocking properties. In some embodiments, the blocking feature 612 is configured as a continuous structure, and has a width measured in the X direction that is not smaller than a width of a respective one of the source/drain portions 62 which are formed in subsequent step (i.e., a spaced apart distance between two adjacent ones of the stack portions 20 shown in FIG. 10).

In some embodiments, the blocking feature 612 is made of silicon oxide with a formula of SiOₓ, or silicon nitride with a formula of SiNₓ, wherein x is larger than 0.5, i.e., oxygen, or nitrogen is present in an amount greater than approximately 33.3 atomic %. In some embodiments, oxygen (or nitrogen) in the blocking feature 612 is present in an amount ranging from about 33.3 atomic % to about 67 atomic %. By having the aforementioned oxygen (or nitrogen) concentration, each of the blocking feature 612 is formed as a continuous oxide layer (or nitride layer). Please note that, in each of the treated base epitaxy layers 61, the undoped upper portion 611 may unavoidably include a small amount of silicon oxide (or silicon nitride), e.g., oxygen (or nitrogen) is present in an amount less than approximately 5 atomic %. In other embodiments, for each of the treated base epitaxy layers 61, at upper surface thereof, i.e., upper surface of the undoped upper portion 611, oxygen (or nitrogen) is present in an amount less than approximately 1 atomic %, such as less than about 5×10²⁰ atoms/cm³. Please note that, the smaller the amount of oxygen (or nitrogen) present at the upper surfaces of the treated base epitaxy layers 61, the more beneficial it is to grow source/drain portions 62 (see FIG. 13) with single crystal structure thereon.

In some embodiments, each of the treated base epitaxy layers 61 is formed to at least partially cover a bottommost pair of the inner spacers 52 in a respective one of the trenches 41. In some embodiments, the blocking feature 612 in each of the treated base epitaxy layers 61 is in direct contact with the bottommost pair of the inner spacers 52 in the respective one of the trenches 41. The upper surface 6120 of the blocking feature 612 is at a level that is between the levels of upper and lower surfaces of the bottommost one of the recessed second nanosheets 222 of each of the two corresponding adjacent ones of the stack portions 20. In some embodiments, the upper surface 6120 of the blocking feature 612 is at a level higher than the level of the bottom surface 2002 of each of the two corresponding adjacent ones of the stack portions 20 by a second height H2. The second height H2 is smaller than the first height H1 (see FIG. 8), and may range from about 3 nm to about 5 nm, but is not limited thereto.

Referring to FIG. 9, a first sub-step of step 106 includes performing an ion implantation process to dope dopants into the base epitaxy layers 610 (see FIG. 8), so as to obtain doped base epitaxy layers 61 each including a doped portion (denoted by the numeral 612, which will be formed into the aforementioned blocking feature 612 by completion of step 106).

In some embodiments, the dopants include oxygen or nitrogen. Since the base epitaxy layers 610 include silicon, the doped portion 612 in each of the doped base epitaxy layers 610 includes silicon oxide (SiOₓ) or silicon nitride (SiNₓ). Dosage of the oxygen (or nitrogen) dopants may be varied based on practical needs and the desired oxygen (or nitrogen) concentration of the blocking feature 612. In some embodiments, the oxygen (or nitrogen) dopants may be applied at a dosage level ranging from about 1×10¹⁶ cm⁻² to about 1×10¹⁸ cm⁻², so that the doped portion 612 may be formed as a continuous oxide layer (or nitride layer). In the case that the dosage level is too low, the oxide layer (or nitride layer) is not continuous and leakage paths may be undesirably formed, which may induce current leakage. In the case that the dosage level is too high, the doped portion 612 may be rough, or may be formed with voids.

The ion implantation process may be performed using any suitable implant tool that provides an energy ranging from about 1 KeV to about 5 KeV so that the dopants are directed to desired position within the base epitaxy layers 610. That is, location of the doped portion 612 may be adjusted by varying the energy applied in order to obtain, by completion of step 106, the blocking feature 612 that is embedded within each of the treated base epitaxy layers 61 (so as to retain the undoped upper portion 611 with single crystal structure) and that is in contact with the bottommost pair of the inner spacers 52 in the respective one of the trenches 41 (so as to prevent current leakage). In addition, a bias may be applied so that the dopants are directed to the base epitaxy layers 610 without affecting other elements of the structure. Please note that the thickness (T2) of the blocking feature 612 may be varied by adjusting energy and/or dosage level of the oxygen (or nitrogen) dopants applied in the ion implantation process.

In certain embodiments, the ion implantation process is performed at a relatively high temperature, such as not less than approximately 500° C., e.g., ranging from about 500° C. to about 700° C. Such high temperature allows the oxygen (or nitrogen) dopants to aggregate at the middle portions of the base epitaxy layers 610 so as to form the doped portions 612 with high quality, and to exert a minimum effect on the single crystal structure of silicon in the upper portions 611 of the doped base epitaxy layers 61. That is, as the doped portions 612 are formed by the ion implantation process at a relatively high temperature, the upper portions 611 are substantially unaffected/undamaged such that the desired single crystal structure can be retained, especially at the upper surfaces on which the source/drain portions 62 (see FIG. 13) are grown. In the case that the ion implantation process is conducted at a relatively low temperature (e.g., less than 500° C.), crystal structure of the upper portions may undesirably become amorphous, and the oxygen (or nitrogen) dopants may be unevenly distributed, which is less favorable to grow source/drain portions 62 with single crystal thereon. After the ion implantation process, the spacers 6101 are removed using any suitable methods known in the art.

Referring to FIG. 10, a second sub-step of step 106 includes annealing the doped base epitaxy layers 610 (each including the doped portion 612). In some embodiments, since the ion implantation process is performed at a temperature greater than about 500° C., the annealing process is conducted at a relatively low temperature ranging from about 800° C. to about 1000° C. In certain embodiments, the annealing process is conducted at a higher temperature, e.g., greater than 1100° C., within approximately 10-3 second. In other cases, when the ion implantation process is performed at a relatively low temperature (e.g. less than about 500° C.), the annealing process is performed at a relatively high temperature (e.g., greater than about 1200° C.). The annealing process improves the quality of silicon crystal in the undoped upper portions 611 of the treated base epitaxy layers 61. In addition, the annealing process is conducive in enhancing segregation of the oxygen (or nitrogen) dopants, so as to permit a more uniform oxygen (or nitrogen) distribution throughout the blocking feature 612, and to make the oxide (or nitride) layers more solid. Specifically, by applying a thermal energy (either in the ion implantation process, or in the annealing process), the oxygen (or nitrogen) dopants tend to aggregate in each of the treated base epitaxy layers 61, in which the aggregation occurs at middle portion thereof (at which oxygen (or nitrogen) concentration is the highest), and, at the upper surface thereof, so as to form a thin oxide (or nitride) film on top of the single crystal silicon. Such thin oxide (or nitride) films at upper surfaces of the treated base epitaxy layers 61 will be removed prior to formation of the source/drain portions 62 (see FIG. 13), and thus are not discussed in the foregoing and are not shown in the figures.

In some embodiments, the second sub-step of performing the annealing process may be omitted if the ion implantation process of the first sub-step already provides the upper portions 611 (of the doped base epitaxy layers 61) that are of good quality with single crystal structure such that the upper portions 611 serve as the undoped upper portions 611 (of the treated base epitaxy layers 61), or provides the doped portions 612 (of the doped base epitaxy layers 61) that are continuous and solid such that the doped portions 612 serve as the blocking features 612 (of the treated base epitaxy layers 61).

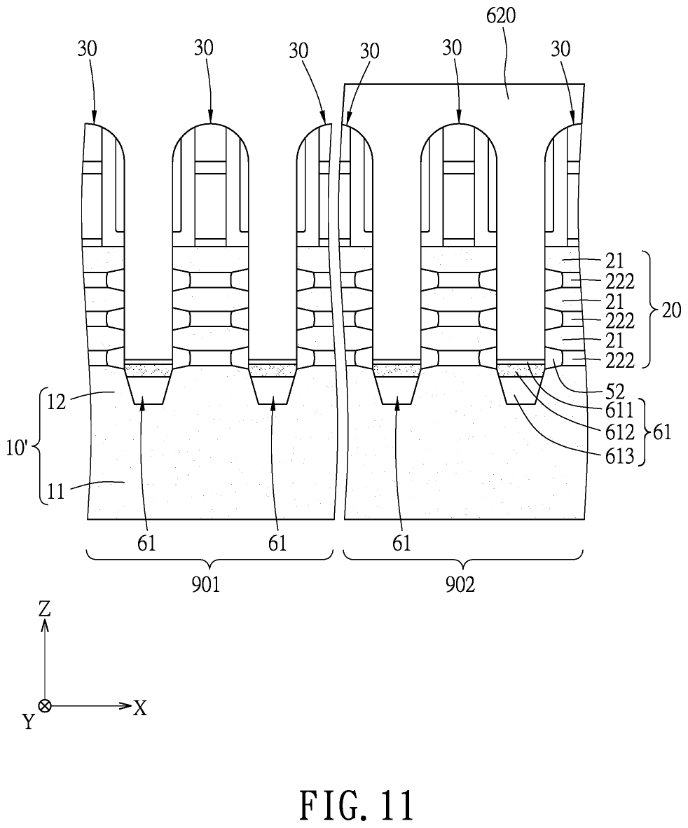

Referring to FIG. 1 and the examples illustrated in FIGS. 11 to 13, the method proceeds to step 107, where source/drain portions 62 are respectively formed in the trenches 41 and on the treated base epitaxy layers 61. Source/drain portion(s) may refer to a source or a drain, individually or collectively dependent upon the context.

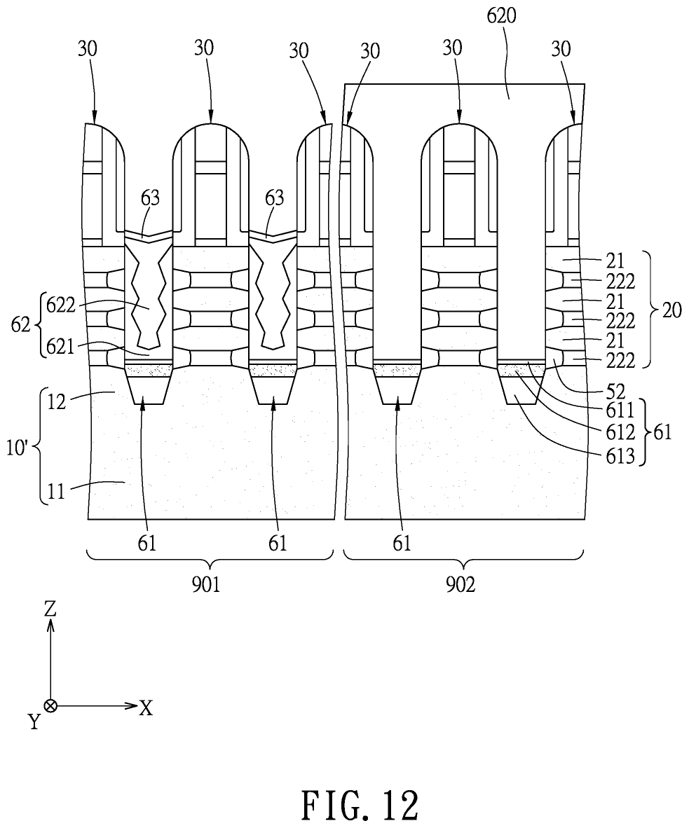

In some embodiments, the source/drain portions 62 located at each of the first and second regions 901, 902 are formed with different materials, and thus are formed separately. For instance, the source/drain portions 62 located at the first region 901 are first formed as illustrated in FIGS. 11 and 12, and the source/drain portions 62 located at the second region 902 are then formed as illustrated in FIG. 13. In other embodiments, vice versa, the source/drain portions 62 located at the second region 902 are first formed, followed by formation of the source/drain portions 62 located at the first region 901.

Referring to FIG. 11, a masking layer 620 is formed over the second region 902 to cover the trenches 41 and the treated base epitaxy layers 61 (see FIG. 10) located at the second region 902, and the trenches 41 and the treated base epitaxy layers 61 located at the first region 901 is exposed from the masking layer 620. The masking layer 620 may include any suitable materials, and may be formed by any suitable processes that are known in the art.

After forming the masking layer 620 at the second region 902, and prior to forming the source/drain portions 62 at the first region 901, an oxide removing process is performed to remove any oxides formed on any silicon surfaces (on which the source/drain portions 62 are grown) exposed from the masking layer 620, especially the oxide films, or damaged portions, if any, formed at the upper surfaces of the treated base epitaxy layers 61 during the ion implantation process in step 106. As such, the silicon surfaces of the treated base epitaxy layers 61 are exposed for a selective epitaxy growing process of the source/drain portions 62. In some embodiments, the oxide removing process is performed using a remote plasma process, but is not limited thereto. The oxide removing process may adopt any suitable chemicals such as nitrogen trifluoride (NF₃) in combination with ammonia (NH₃), or hydrogen fluoride (HF) in combination with ammonia (NH₃), or the likes. Please note that formation of the n-type source/drain portions 62 at the first region 901 follows immediately after the oxide removing process at the first region 901, while formation of the p-type source/drain portions 62 at the second region 902 follows immediately after the oxide removing process at the second region 902.

Referring to FIG. 12, the source/drain portions 62 are respectively formed on the exposed ones of the treated base epitaxy layers 61 by any suitable epitaxy growing processes such as chemical vapour deposition (CVD), or molecular beam epitaxy (MBE), but are not limited thereto.

In some embodiments, each of the source/drain portions 62 includes one or more epitaxy layers, depending on practical needs and product designs. The different epitaxy layers may each includes a silicon-based semiconductor material and may respectively include different concentration of dopants. For instance, as shown in FIG. 12, each of the source/drain portions 62 at the first region 901 includes a first epitaxy layer 621, and a second epitaxy layer 622 that are sequentially formed.

Please note that the epitaxy growth process is a selective growth process, in which the source/drain portions 62 are grown from the silicon surfaces (e.g., lateral surfaces of the first nanosheets 21 and the upper surfaces of the treated base epitaxy layers 61) at the first region 901.

In each of the trenches 41 at the first region 901, lateral surfaces of the first nanosheets 21 of two corresponding adjacent ones of the stack portions 20, and the upper surface of the corresponding one of the treated base epitaxy layers 61 are accessible for growing thereon the corresponding one of the source/drain portions 62. As such, each of the source/drain portions 62 is grown from the lateral surfaces of the corresponding first nanosheets 21 (in a lateral manner) and from the upper surface of the corresponding base epitaxy layer 61 (in a bottom-up manner). The source/drain portions 62 formed thereby are more likely to have an enhanced quality, e.g., single crystal structure (especially when the upper surfaces of the treated base epitaxy layers 61 are formed with single crystal structure), and with only small amount of voids, which is conducive to providing a desired channel strain to the first nanosheets 21 that serve as the channel nanosheets of nanosheet transistor(s) at the first region 901. In the case that the upper surfaces of the base epitaxy layers are not made of silicon, the source/drain portions are formed by merely laterally growing the same from the first nanosheets, and are likely to be formed with more voids or defects in comparison with the source/drain portions 62 formed in accordance to the epitaxy growth process of the present disclosure.

In addition, because of the selective growth property, portions of the first epitaxy layers 621 that are formed at the first nanosheets 21 and at the treated base epitaxy layers 61 are relatively thick. Such portions grow and merge to form thinner portions at the inner spacers 52. The second epitaxy layers 622 are respectively grown on the first epitaxy layers 621 and respectively fill the trenches 41. In some embodiments, capping layers 63 are respectively formed on the source/drain portions 62. In some embodiments, the capping layers 63 are configured to form metal silicides (not shown).

In some embodiments, for the n-type first region 901, the source/drain portions 62 and the capping layers 63 may include any suitable semiconductor material and any suitable n-type dopant. For instance, the semiconductor material may be silicon, and the n-type dopant may be arsenic, phosphorus, antimony, bismuth, or the likes, or combinations thereof. In some embodiments, at the first epitaxy layers 621, arsenic may be present in an amount ranging from about 2×10²⁰ atoms/cm³ to about 1×10²¹ atoms/cm³. At the second epitaxy layers 622, phosphorus may be present in an amount ranging from about 1×10²⁰ atoms/cm³ to about 1×10²¹ atoms/cm³. At the capping layers 63, phosphorus may be present in an amount ranging from about 1×10²¹ atoms/cm³ to about 6×10²¹ atoms/cm³. Other suitable materials and/or dopant concentration for the source/drain portions 62 at the n-type first region 901 are within the contemplated scope of the present disclosure.

After completing formation of the n-type source/drain portions 62 at the first region 901, referring to FIG. 13, the p-type source/drain portions 62 are formed at the second region 902 in a manner similar to those described with reference to FIGS. 11 to 12, except that materials are different.

Specifically, firstly, the mask layer 620 at the second region 902 (see FIG. 12) is removed, while another mask layer 630 is formed to cover the source/drain portions 62 at the first region 901 (see the description with reference to FIG. 11). In addition, after forming the masking layer 630 at the first region 901, and prior to forming the source/drain portions 62 at the second region 902, another oxide removing process (similar to the oxide removing process performed at the first region 901) is performed to remove any oxides formed on any silicon surfaces (e.g., the lateral surfaces of the first nanosheets 21 and the upper surfaces of the treated base epitaxy layers 61) at the second region 902.

Then, the source/drain portions 62 at the second region 902 are formed by an epitaxy growing process. In some embodiments, at the p-type second region 902, the source/drain portions 62 and the capping layers 63 may include any suitable semiconductor material and any suitable p-type dopants. For instance, the semiconductor material includes silicon and/or silicon germanium, and the p-type dopants are boron, aluminum, gallium, indium, thallium or the likes, or combinations thereof. In some embodiments, the p-type first epitaxy layers 621 may include silicon that is doped with boron in an amount ranging from about 1×10²⁰ atoms/cm³ to about 1×10²¹ atoms/cm³. The second epitaxy layers 622 may include silicon germanium doped with boron, wherein germanium is present in an amount ranging from about 12 atomic % to about 20 atomic %, and boron is present in an amount ranging from about 1×10²⁰ atoms/cm³ to about 1×10²¹ atoms/cm³. The capping layers 63 may include silicon germanium doped with boron, wherein germanium is present in an amount ranging from about 40 atomic % to about 70 atomic %, and boron is present in an amount ranging from about 1×10²¹ atoms/cm³ to about 6×10²¹ atoms/cm³. Other suitable materials and/or dopant concentration for the source/drain portions 62 at the p-type first region 902 are within the contemplated scope of the present disclosure.

After forming the source/drain portions 62 at the second region 902. The masking layer 630 covering the first region 901 is removed.

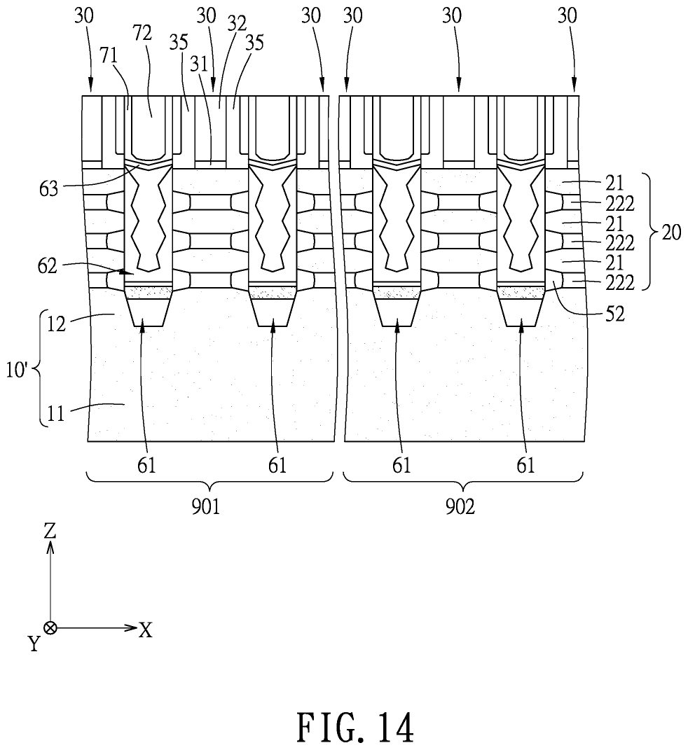

Referring to FIG. 1 and the example illustrated in FIG. 14, the method proceeds to step 108, where a plurality of contact etch stop layers (CESLs) 71 and a plurality of interlayer dielectrics (ILDs) 72 are sequentially formed on the source/drain portions 62 (at both the first and second regions 901, 902), respectively.

In some embodiments, each of the CESLs 71 and the ILDs 72 include a dielectric material such as silicon oxide, silicon nitride, or the like, or combinations thereof. The dielectric material of the CESLs 71 is different from the dielectric material of the ILDs 72. In some embodiments, step 108 includes sequentially forming two dielectric material layers (respectively for forming the CESLs 71 and the ILDs 72) over the structure shown in FIG. 13 using any suitable deposition process, followed by a planarization process to remove an excess amount of the two dielectric material layers, and to remove the polish stop layer 33, the hard mask 34 and portions of the gate spacers 35 in each of the gate structures 30 (see FIG. 13) so as to expose the dummy gate 32 in each of the gate structures 30. Other suitable materials and/or processes for forming the CESLs 71 and the ILDs 72 are within the contemplated scope of the present disclosure.

Referring to FIG. 1 and the example illustrated in FIG. 15, the method proceeds to step 109, where a plurality of gate units 80 are formed, each of which includes a gate dielectric 81 and a gate electrode 82.

In some embodiments, step 109 may include the following sub-steps: removing the dummy dielectrics 31 and the dummy gates 32 of the gate structures 30 and the recessed second nanosheets 222 (see FIG. 14) to form a pluralities of cavities (not shown) using any suitable etching processes; sequentially depositing a gate dielectric material (for forming the gate dielectric 81) and a gate electrode material (for forming the gate electrode 82) in the cavities; and removing any excess amount of the gate dielectric material and the gate electrode material, thereby obtaining the gate units 80 respectively in the cavities, and thus the nanosheet transistors.

In some embodiments, the gate dielectric 81 includes a dielectric material, such as a high dielectric constant material (e.g., hafnium oxide), but is not limited thereto. The gate electrode 82 may include a conductive material such as a metal, a metal-containing nitride, a metal-containing silicide, a metal-containing carbides, but is not limited thereto. Other suitable materials and/or processes for forming the gate dielectric 81 and the gate electrode 82 are within the contemplated scope of the present disclosure. In some embodiments, step 109 may further include sub-steps of etching back portions of each of the gate units 80; depositing a suitable dielectric material; and a planarization process (e.g., CMP, but is not limited thereto), so as to obtain a plurality of self-aligned dielectric features 83. The self-aligned dielectric features 83 are respectively disposed on the etched-back gate units 80.

After step 109, as shown in FIG. 15, a first nanosheet transistor is formed on the first region 901, and includes first channel nanosheets 21A (i.e., a middle stack of the first nanosheets 21 on the first region 901), two first source/drain portions 62A (i.e., the source/drain portions 62 on the first region 901), and a first gate unit 80A (i.e., a middle one of the gate units 80 on the first region 901). The first channel nanosheets 21A are spaced apart from each other in the Z direction. The first gate unit 80A is disposed to surround the first channel nanosheets 21A. The first source/drain portions 62A are spaced apart from each other by the first channel nanosheets 21A in the X direction, and are respectively disposed on two first treated base epitaxy layers 61A (i.e., two of the treated base epitaxy layers 61 on the first region 901). Each of the first treated base epitaxy layers 61A includes the undoped upper portion 611 (which is connected to a respective one of the first source/drain portions 62A), the doped middle portion 612 (which is also known as a blocking feature 612 and which is separated from the respective first source/drain portion 62A through the undoped upper portion 611), and the undoped lower portion 613. The first nanosheet transistor also includes multiple pairs of first inner spacers 52 A (each pair of which is disposed under the two ends of a respective one of the first channel nanosheets 21A). A bottommost pair of the first inner spacers 52A is in contact with the blocking features 612 of the two first treated base epitaxy layers 61A, respectively. The blocking features 612 of the two first treated base epitaxy layers 61A are each a continuous silicon oxide (SiOₓ) layer, wherein x is larger than 0.5. Each of the first source/drain portions 62A is isolated from the patterned substrate 10′ through the blocking feature 612 of a respective one of the two first treated base epitaxy layers 61A. The first gate unit 80A includes a first gate portion 8A which is sandwiched between the substrate 10′ and a bottommost one of the first nanosheets 21 A from a respective one of the stack portions 20 (see also FIG. 14). A first bottom surface 8A1 of the first gate portion 8A is at a level that is lower than a level of the upper surface 6100 of each of the first treated base epitaxy layers 61A, and that is lower than a level of the upper surface 6120 of the blocking feature 612 in each of the first treated base epitaxy layers 61A.

Similarly, a second nanosheet transistor is formed on the second region 902, and includes second channel nanosheets 21B (i.e., a middle stack of the first nanosheets 21 on the second region 902), two second source/drain portions 62B (i.e., the source/drain portions 62 on the second region 902), and a second gate unit 80B (i.e., a middle one of the gate units 80 on the second region 902). The second channel nanosheets 21B are spaced apart from each other in the Z direction. The second gate unit 80B is disposed to surround the second channel nanosheets 21B. The second source/drain portions 62B are spaced apart from each other by the second channel nanosheets 21B in the X direction, and are respectively disposed on two second treated base epitaxy layers 61B (i.e., two of the treated base epitaxy layers 61 on the second region 902). Each of the second treated base epitaxy layers 61B includes the undoped upper portion 611 (which is connected to a respective one of the second source/drain portions 62B), the doped middle portion 612 (which is also known as a blocking feature 612 and which is separated from the respective second source/drain portions 62B through the undoped upper portion 611), and the undoped lower portion 613. The second nanosheet transistor also includes multiple pairs of second inner spacers 52B (each pair of which is disposed under the two ends of a respective one of the second channel nanosheets 21B). A bottommost pair of the second inner spacers 52B is in contact with the blocking features 612 of the two second treated base epitaxy layers 61B, respectively. The blocking features 612 of the two second treated base epitaxy layers 61B are each a continuous silicon oxide (SiOₓ) layer, wherein x is larger than 0.5. Each of the second source/drain portions 62B is isolated from the patterned substrate 10′ through the blocking feature 612 of a respective one of the two second treated base epitaxy layers 61B. The second gate unit 80B includes a second gate portion 8B which is sandwiched between the substrate 10′ and a bottommost one of the second nanosheets 21B from a respective one of the stack portions 20 (see also FIG. 14). A second bottom surface 8B1 of the second gate portion 8B is at a level that is lower than a level of the upper surface 6100 of each of the second treated base epitaxy layers 61A, and that is lower than a level of the upper surface 6120 of the blocking feature 612 in each of the second treated base epitaxy layers 61B.

The embodiments of the present disclosure have the following advantageous features. The blocking features 612 are respectively formed inside the treated base epitaxy layers 61 so that the upper portions 611 of the treated base epitaxy layers serve as the growing surfaces of the source/drain portions 62, respectively. Such blocking features 612 are formed by performing an ion implantation process at a relatively high temperature. As such, the single crystal structure of silicon of the upper portions 611 is retained to promote formation of the source/drain portions 62 with good quality, so that the channel nanosheets 21 are provided with improved strain.

In accordance with some embodiments of the present disclosure, a method for manufacturing a semiconductor structure includes: forming stacks on a substrate; forming gate structures on the stacks, the gate structures being spaced apart from each other such that portions of the stacks are exposed from the gate structures; forming trenches respectively in the portions of the stacks and respectively extending into upper portions of the substrate, after forming the trenches, each of the stacks being formed into stack portions each including first nanosheets, and second nanosheets that alternate with the first nanosheets; forming base epitaxy layers respectively at bottoms of the trenches; performing an ion implantation process to dope dopants into the base epitaxy layers so as to obtain doped base epitaxy layers, each of which is embedded with a blocking feature; and forming source/drain portions respectively in the trenches on the doped base epitaxy layers such that each of the source/drain portions is isolated from the substrate through the blocking feature in a respective one of the doped base epitaxy layers.

In accordance with some embodiments of the present disclosure, the dopants include one of oxygen and nitrogen.

In accordance with some embodiments of the present disclosure, in the ion implantation process, a dosage level of the dopants is in a range from 1×10¹⁶ cm⁻² to 1×10¹⁸ cm⁻².

In accordance with some embodiments of the present disclosure, the ion implantation process is performed at a temperature not less than 500° C.

In accordance with some embodiments of the present disclosure, the method further includes, after the ion implantation process and prior to forming the source/drain portions, performing an annealing process to anneal the doped base epitaxy layers.

In accordance with some embodiments of the present disclosure, the method further includes, after forming the trenches and prior to forming the base epitaxy layers, recessing the second nanosheets of each two adjacent ones of the stack portions through a respective one of the trenches, so as to form multiple pairs of lateral recesses; and forming multiple pairs of inner spacers respectively in the multiple pairs of lateral recesses.

In accordance with some embodiments of the present disclosure, the blocking feature in each of the doped base epitaxy layers is in direct contact with a bottommost pair of the inner spacers in the respective one of the trenches.

In accordance with some embodiments of the present disclosure, in forming the base epitaxy layers, an upper surface of each of the base epitaxy layers is at a level higher than a level of a bottom surface of each of two corresponding adjacent ones of the stack portions.

In accordance with some embodiments of the present disclosure, the blocking feature in each of the doped base epitaxy layers is configured as a continuous structure and has a width that is not smaller than a width of a respective one of the source/drain portions.

In accordance with some embodiments of the present disclosure, a method for manufacturing a semiconductor structure includes: forming stacks on a substrate; forming gate structures on the stacks, the gate structures being spaced apart from each other such that portions of the stacks are exposed from the gate structures; forming trenches respectively in the portions of the stacks and respectively extending into upper portions of the substrate, after forming the trenches, each of the stacks being formed into stack portions each including first nanosheets and second nanosheets that alternate with the first nanosheets; forming treated base epitaxy layers respectively at bottoms of the trenches, each of the treated base epitaxy layers including an undoped upper portion, an undoped lower portion, and a doped middle portion interposed between the undoped lower portion and the undoped upper portion; and forming source/drain portions respectively in the trenches on the treated base epitaxy layers such that each of the source/drain portions is isolated from the substrate through the doped middle portion of a respective one of the treated base epitaxy layers.

In accordance with some embodiments of the present disclosure, forming the treated base epitaxy layers includes: forming base epitaxy layers respectively at the bottoms of the trenches; performing an ion implantation process to dope dopants into middle portions of the base epitaxy layers; and after performing the ion implantation process, performing an annealing process to anneal the base epitaxy layers, so that the base epitaxy layers are formed into the treated base epitaxy layers.

In accordance with some embodiments of the present disclosure, the method further includes after forming the trenches and prior to forming the base epitaxy layers, recessing the second nanosheets of each two adjacent ones of the stack portions through a respective one of the trenches, so as to form multiple pairs of lateral recesses; and forming multiple pairs of inner spacers respectively in the multiple pairs of the lateral recesses.

In accordance with some embodiments of the present disclosure, each of the treated base epitaxy layers is formed to at least partially cover a bottommost pair of the inner spacers in the respective one of the trenches.

In accordance with some embodiments of the present disclosure, for each of the treated epitaxy layers, the doped middle portion is covered by the undoped upper portion.

In accordance with some embodiments of the present disclosure, for each of the treated epitaxy layers, the undoped upper portion fully covers the doped middle portion.

In accordance with some embodiments of the present disclosure, a semiconductor structure includes a substrate; channel nanosheets; a gate unit; two source/drain portions and two base epitaxy layers. The channel nanosheets are disposed above the substrate and are spaced apart from each other in a Z direction. Each of the channel nanosheets has two ends that are opposite to each other in an X direction transverse to the Z direction. The gate unit is disposed around the channel nanosheets. The two source/drain portions are spaced apart from each other by the channel nanosheets in the X direction. The two base epitaxy layers are respectively located under the two source/drain portions. Each of the two base epitaxy layers includes an undoped upper portion, and a doped portion that is disposed beneath the undoped upper portion and that is separated from a respective one of the two source/drain portions by the undoped upper portion.

In accordance with some embodiments of the present disclosure, the semiconductor structure further includes pairs of inner spacers, each pair of which is respectively disposed under the two ends of a respective one of the channel nanosheets. A bottommost pair of the inner spacers is in direct contact with the doped portion of a respective one of the two base epitaxy layers.

In accordance with some embodiments of the present disclosure, the doped portion of each of the two base epitaxy layers is configured as a continuous structure.

In accordance with some embodiments of the present disclosure, the undoped upper portion is a silicon-based semiconductor portion, and the doped portion includes SiOₓ, where x is larger than 0.5.

In accordance with some embodiments of the present disclosure, the gate unit includes a gate portion which is sandwiched between the substrate and a bottommost one of the channel nanosheets, a bottom surface of the gate portion being at a level lower than a level of an upper surface of each of the two base epitaxy layers.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming stacks on a substrate;
forming gate structures on the stacks, the gate structures being spaced apart from each other such that portions of the stacks are exposed from the gate structures;
forming trenches respectively in the portions of the stacks and respectively extending into upper portions of the substrate, after forming the trenches, each of the stacks being formed into stack portions each including first nanosheets, and second nanosheets that alternate with the first nanosheets;
forming base epitaxy layers respectively at bottoms of the trenches;
performing an ion implantation process to dope dopants into the base epitaxy layers so as to obtain doped base epitaxy layers, each of which is embedded with a blocking feature; and
forming source/drain portions respectively in the trenches on the doped base epitaxy layers such that each of the source/drain portions is isolated from the substrate through the blocking feature in a respective one of the doped base epitaxy layers.

2. The method according to claim 1, wherein the dopants include one of oxygen and nitrogen.

3. The method according to claim 2, wherein, in the ion implantation process, a dosage level of the dopants is in a range from 1×10¹⁶ cm⁻² to 1×10¹⁸ cm⁻².

4. The method according to claim 1, wherein the ion implantation process is performed at a temperature not less than 500° C.

5. The method according to claim 1, further comprising, after the ion implantation process and prior to forming the source/drain portions, performing an annealing process to anneal the doped base epitaxy layers.

6. The method according to claim 1, further comprising, after forming the trenches and prior to forming the base epitaxy layers,
recessing the second nanosheets of each two adjacent ones of the stack portions through a respective one of the trenches, so as to form multiple pairs of lateral recesses; and
forming multiple pairs of inner spacers respectively in the multiple pairs of lateral recesses.

7. The method according to claim 6, wherein the blocking feature in each of the doped base epitaxy layers is in direct contact with a bottommost pair of the inner spacers in the respective one of the trenches.

8. The method according to claim 1, wherein in forming the base epitaxy layers, an upper surface of each of the base epitaxy layers is at a level higher than a level of a bottom surface of each of two corresponding adjacent ones of the stack portions.

9. The method according to claim 1, wherein the blocking feature in each of the doped base epitaxy layers is configured as a continuous structure and has a width that is not smaller than a width of a respective one of the source/drain portions.

10. A method for manufacturing a semiconductor structure, comprising:
forming stacks on a substrate;
forming gate structures on the stacks, the gate structures being spaced apart from each other such that portions of the stacks are exposed from the gate structures;
forming trenches respectively in the portions of the stacks and respectively extending into upper portions of the substrate, after forming the trenches, each of the stacks being formed into stack portions each including first nanosheets and second nanosheets that alternate with the first nanosheets;
forming treated base epitaxy layers respectively at bottoms of the trenches, each of the treated base epitaxy layers including an undoped upper portion, an undoped lower portion, and a doped middle portion interposed between the undoped lower portion and the undoped upper portion; and
forming source/drain portions respectively in the trenches on the treated base epitaxy layers such that each of the source/drain portions is isolated from the substrate through the doped middle portion of a respective one of the treated base epitaxy layers.

11. The method according to claim 10, wherein forming the treated base epitaxy layers includes:
forming base epitaxy layers respectively at the bottoms of the trenches;
performing an ion implantation process to dope dopants into middle portions of the base epitaxy layers; and
after performing the ion implantation process, performing an annealing process to anneal the base epitaxy layers, so that the base epitaxy layers are formed into the treated base epitaxy layers.

12. The method according to claim 11, further comprising, after forming the trenches and prior to forming the base epitaxy layers, recessing the second nanosheets of each two adjacent ones of the stack portions through a respective one of the trenches, so as to form multiple pairs of lateral recesses; and
forming multiple pairs of inner spacers respectively in the multiple pairs of the lateral recesses.

13. The method according to claim 12, wherein each of the treated base epitaxy layers is formed to at least partially cover a bottommost pair of the inner spacers in the respective one of the trenches.

14. The method according to claim 10, wherein for each of the treated epitaxy layers, the doped middle portion is covered by the undoped upper portion.

15. The method according to claim 14, wherein for each of the treated epitaxy layers, the undoped upper portion fully covers the doped middle portion.

16. A semiconductor structure, comprising:
a substrate;
channel nanosheets that are disposed above the substrate and that are spaced apart from each other in a Z direction, each of the channel nanosheets having two ends that are opposite to each other in an X direction transverse to the Z direction;
a gate unit disposed around the channel nanosheets;
two source/drain portions that are spaced apart from each other by the channel nanosheets in the X direction; and
two base epitaxy layers respectively located under the two source/drain portions, each of the two base epitaxy layers including an undoped upper portion, and a doped portion that is disposed beneath the undoped upper portion and that is separated from a respective one of the two source/drain portions by the undoped upper portion.

17. The semiconductor structure according to claim 16, further comprising pairs of inner spacers, each pair of which is respectively disposed under the two ends of a respective one of the channel nanosheets, wherein a bottommost pair of the inner spacers is in direct contact with the doped portion of a respective one of the two base epitaxy layers.

18. The semiconductor structure according to claim 17, wherein the doped portion of each of the two base epitaxy layers is configured as a continuous structure.

19. The semiconductor structure according to claim 16, wherein the undoped upper portion is a silicon-based semiconductor portion, and the doped portion includes one of SiOₓ and SiNₓ, where x is larger than 0.5.

20. The semiconductor structure according to claim 16, wherein the gate unit includes a gate portion which is sandwiched between the substrate and a bottommost one of the channel nanosheets, a bottom surface of the gate portion being at a level lower than a level of an upper surface of each of the two base epitaxy layers.
